(19) United States
(12) Patent Application Publication
(10) Pub. No.: US 2025/0212594 A1
(43) Pub. Date: Jun. 26, 2025

(54) COMPOSITE FILM, PREPARATION METHOD THEREOF AND LIGHT-EMITTING DEVICE

(71) Applicant: TCL Technology Group Corporation, Huizhou (CN)

(72) Inventor: Xiongfeng LIN, Huizhou (CN)

(73) Assignee: TCL Technology Group Corporation, Huizhou (CN)

(21) Appl. No.: 18/986,678

(22) Filed: Dec. 18, 2024

(30) Foreign Application Priority Data
Dec. 25, 2023 (CN) 202311804394.1

(51) Int. Cl. H10K 50/11; B82Y 20/00; B82Y 40/00; C09K 11/08; C09K 11/54; C09K 11/60; C09K 11/67; C09K 11/68; C09K 11/70; C09K 11/88; C23C 16/34; C23C 16/455; H10K 50/155; H10K 50/165

(52) U.S. Cl. CPC H10K 50/11; C09K 11/0883; C09K 11/54; C09K 11/60; C09K 11/67; C09K 11/681; C09K 11/70; C09K 11/883; C23C 16/34; C23C 16/45553; H10K 50/155; H10K 50/165; B82Y 20/00; B82Y 40/00

(57) ABSTRACT

The present disclosure composite film, preparation method thereof and light-emitting device. A composite film, includes X layers of first film and Y layers of second film alternately stacked, wherein X is an integer ≥1 and Y is an integer ≥1. A material of the first film includes inorganic nanoparticle, and a material of the second film includes inorganic metal compound. The composite film provided by the present disclosure has good bending resistance.

This application claims priority to Chinese Application No. 202311804394.1, entitled “COMPOSITE FILM, PREPARATION METHOD THEREOF, LIGHT-EMITTING DEVICE AND DISPLAY DEVICE”, filed on Dec. 25, 2023. The entire disclosures of the above application are incorporated herein by reference.

### TECHNICAL FIELD

The present disclosure relates to a field of display technologies, and more particularly, to composite film, preparation method thereof and light-emitting device.

### BACKGROUND

At present, flexible photoelectric devices have shown broad application prospects and improved the convenience and intelligence of life because of their good flexibility. Quantum dots are widely used in photoelectric devices because of their adjustable spectrum, high luminous intensity, high colour purity, long fluorescence life and multi-colour fluorescence excited by light source.

Inorganic nanoparticles are often used as the materials of carrier functional layer and luminescent layer in photoelectric devices. However, due to the properties of nanoparticles, in the bending process of flexible photoelectric devices, they are often accompanied by the displacement of nanoparticles, resulting in cracks or even breaks in the film, which changes the charge transmission of photoelectric devices, leads to the decline of photoelectric devices, shortens the service life of photoelectric devices and affects the development of flexible photoelectric devices.

In the related art, the bending resistance of functional layer films needs to be further improved.

### Technical Solution

In view of this, the present disclosure provides a composite film, a preparation method thereof and a light-emitting device.

The present disclosure provides a film. The composite film includes X layers of first film; and Y layers of second film alternately stacked with X layers of the first film; wherein X is an integer ≥1 and Y is an integer ≥1. A material of the first film comprises inorganic nanoparticle, and a material of the second film comprises inorganic metal compound.

The present disclosure provides a preparation method of a composite film, includes: providing a first film, wherein a material of the first film comprises inorganic nanoparticle: forming a second film on the first film, wherein a material of the second film comprises inorganic metal compound; and alternately forming X-1 layers of first film and Y-1 layers of second film on the second film in turn, wherein X≥1 and Y≥1 to obtain a composite film.

The present disclosure provides another preparation method of a composite film, includes: providing a second film, wherein a material of the second film comprises inorganic metal compound, forming a first film on the second film, wherein a material of the first film comprises inorganic nanoparticle; and alternately forming Y-1 layers of second film and X-1 layers of first film on the first film in turn, wherein X≥1 and Y≥1 to obtain a composite film.

The present disclosure provides a light-emitting device, includes: an anode; a cathode; and a functional layer, between the anode and the cathode, comprising a composite film, and the composite film includes: X layers of first film; and Y layers of second film alternately stacked with X layers of the first film. Wherein X is an integer ≥1 and Y is an integer ≥1, and a material of the first film comprises inorganic nanoparticle, and a material of the second film comprises inorganic metal compound.

The composite film provided by the present disclosure has good bending resistance.

### BRIEF DESCRIPTION OF DRAWINGS

In order to more clearly explain the technical solutions in the embodiments of the present disclosure, the following will briefly introduce the drawings required in the description of the embodiments. Obviously, the drawings in the following description are only some embodiments of the present disclosure. For those skilled in the art, without paying any creative work, other drawings can be obtained based on these drawings.

FIG. 1 is a schematic diagram of the structure of a composite film according to an embodiment of the present disclosure.

FIG. 2 is a schematic diagram of the structure of a composite film according to another embodiment of the present disclosure.

FIG. 3 is a schematic diagram of the structure of a composite film according to another embodiment of the present disclosure.

FIG. 4 is a flowchart of a method for preparing a composite film according to an embodiment of the present disclosure.

FIG. 5 is a flowchart of a method for preparing a composite film according to another embodiment of the present disclosure.

FIG. 6 is a schematic diagram of the structure of a light-emitting device according to an embodiment of the present disclosure.

FIG. 7 is a schematic diagram of the structure of a light-emitting device according to another embodiment of the present disclosure.

FIG. 8 is a schematic diagram of the structure of a light-emitting device according to v embodiment of the present disclosure.

FIG. 9 is a schematic diagram of the structure of a light-emitting device according to another embodiment of the present disclosure.

### DETAILED DESCRIPTION

Technical solutions in embodiments of the present disclosure will be clearly and completely described below in conjunction with drawings in the embodiments of the present disclosure. Obviously, the described embodiments are only a part of embodiments of the present disclosure, rather than all the embodiments. Based on the embodiments in the present disclosure, all other embodiments obtained by those skilled in the art without creative work fall within the protection scope of the present disclosure.

Additionally, in the description of the present disclosure, the term “comprising/including” means “comprising/including but not limited to.” Various embodiments of the present disclosure may be presented in a form of range. It should be understood that the description in the form of range is merely for convenience and brevity, and should not be construed as a hard limitation on the scope of the disclosure. Accordingly, it should be considered that the recited range description has specifically disclosed all possible subranges, as well as a single numerical value within that range. For example, it should be considered that a description of a range from 1 to 6 has specifically disclosed subranges, such as from 1 to 3, from 1 to 4, from 1 to 5, from 2 to 4, from 2 to 6, from 3 to 6, etc., and a single number within the range, such as 1, 2, 3, 4, 5, and 6, regardless of the range. Whenever a range of values is indicated herein, it is meant to include any recited number (fraction or integer) within the indicated range.

In the present disclosure, the term “and/or” is used to describe the association of associated objects, and means that there may be three relationships, for example, “A and/or B” may refer to three cases: the first case refers to the presence of A alone; the second case refers to the presence of both A and B; the third case refers to the presence of B alone, where A and B may be singular or plural.

In the present disclosure, the term “at least one” refers to one or more, and “a plurality of/multiple” refers to two or more. The terms “at least one”, “at least one of the followings”, or the like, refer to any combination of the items listed, including any combination of the singular or the plural items. For example, “at least one of a, b, or c” or “at least one of a, b, and c” may refer to: a, b, c, a-b (i.e., a and b), a-c, b-c, or a-b-c, where a, b, and c may be single or plural.

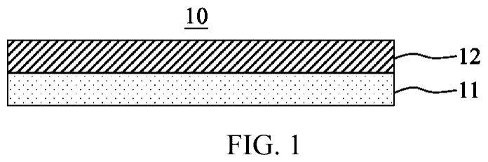

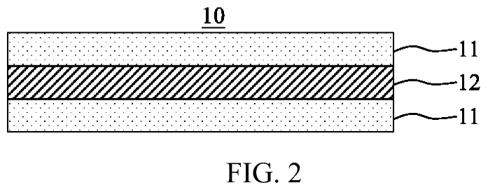

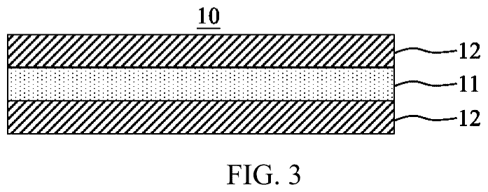

Referring to FIG. 1, FIG. 2 and FIG. 3, the present disclosure discloses a composite film 10, including: X layers of first film 11 and Y layers of second film 12 alternately stacked, wherein X is an integer ≥1 and Y is an integer ≥1. A material of the first film 11 includes inorganic nanoparticle, and a material of the second film 12 includes inorganic metal compound.

It should be noted that the inorganic metal compound provided by this present disclosure includes a tough material. Toughness indicates the ability of a material to absorb energy during plastic deformation and fracture, and it is also the resistance of a material to fracture when it is subjected to a force that causes it to deform. Tough material refers to a material that can bear and absorb a lot of energy and is not easy to break or deform when subjected to external force. Tough material has high ductility and toughness and can maintain stability in extreme environment.

In the composite film provided by this present disclosure, the second film 12 can strengthen the connection between inorganic nanoparticle in the first film 11, avoid the problem of displacement of inorganic nanoparticle when the composite film 10 is bent, and improve the bending resistance of the composite film 10. Moreover, the material of the first film 11 and the second film 12 are both inorganic materials, which have good adaptability. The second film 12 can ensure that the performance of the first film 11, such as carrier migration performance, luminous performance, electrical conductivity and the like, will not be reduced due to the addition of the second film 12.

In some embodiments, X=Y+x, and x is 0 or 1.

In some embodiments, referring to FIG. 1, X=Y. In other words, one side of a first film 11 is provided with a second film 12, while the other side is not provided with a second film 12.

In some embodiments, referring to FIG. 2, X=Y+1. In other words, any second film 12 is disposed between two first film 11.

In some embodiments, referring to FIG. 3, X=Y−1. In other words, any first film 11 is disposed between two second film 12.

In some embodiments, an average particle size of the inorganic nanoparticle ranges between 1 nm-20 nm, such as 2 nm, 5 nm, 8 nm, 10 nm, 12 nm, 15 nm, and 18 nm, etc.

In some embodiments, the inorganic nanoparticle is selected from one of quantum dot, n-type semiconductor nanoparticle and p-type semiconductor nanoparticle.

The quantum dot is selected from one or more of single-structure quantum dot, core-shell quantum dot and perovskite semiconductor material.

A material of the single-structure quantum dot, a core material of the core-shell quantum dot and a shell material of the core-shell quantum dot can be respectively selected from but not limited to one or more of second II-VI compound, second IV-VI compound, second III-V compound and I-III-VI compound. A shell layer of the core-shell structure quantum dot comprises one or more layers. The second II-VI compound is selected from one or more of CdS, CdSe, CdTe, ZnS, ZnSe, ZnTe, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe and HgZnSTe. The second IV-VI compound is selected from one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe and SnPbSTe. The second III-V compound is selected from one or more of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GalnNAs, GalnNSb, GalnPAs, GalnPSb, InAlNP, InAlNAs, InAlNSb, InAlPAs and InAlPSb. The I-III-VI compound is selected from one or more of CuInS₂, CuInSe₂ and AgInS₂.

As an example, the core-shell quantum dot is selected from one or more of CdSe/CdSeS/CdS, InP/ZnSeS/ZnS, CdZnSe/ZnSe/ZnS, CdSe/ZnS, CdSe/ZnSe, ZnSe/ZnS, ZnSe/ZnS, ZnSe/ZnS, and ZnSe/ZnSe/ZnSe.

The perovskite semiconductor material is selected from one of doped or undoped inorganic perovskite semiconductor or organic-inorganic hybrid perovskite semiconductor. A general structural formula of the inorganic perovskite semiconductor is AMZ₃, wherein A is Cs⁺, and M is divalent metal cation, which is selected from one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺ and Eu²⁺, and Z is a halogen anion selected from one or more of Cl⁻, Br⁻ and I⁻. The general structural formula of the organic-inorganic hybrid perovskite semiconductor is BMZ3, wherein B is an organic amine cation selected from CH₃(CH₂)ₙ₋₂NH₃⁺ or [NH₃(CH₂)ₙNH₃]²⁺, wherein n≥2, and M is a divalent metal cation selected from Pb²⁺, Sn²⁺, Cu²⁺, Ni²⁺, Cd²⁺ and Cr³⁺, and Z is a halogen anion selected from one or more of Cl⁻, Br⁻ and I⁻.

In some embodiments, the n-type semiconductor nanoparticle is selected from one or more of first doped metal oxide particle, first undoped metal oxide particle, IIB-VIA semiconductor material, IIIA-VA semiconductor material and IB-IIIA-VIA semiconductor material. A material of the first undoped metal oxide particle is selected from one or more of ZnO, TiO₂, SnO₂, ZrO₂ and Ta₂O₅. A metal oxide in the first doped metal oxide particle is selected from one or more of ZnO, TiO₂, SnO₂, ZrO₂, Ta₂O₅ and Al₂O₃. A doping element in the first doped metal oxide particle is selected from one or more of Al, Mg, Li, Mn, Y, La, Cu, Ni, Zr, Ce, In and Ga. The IIB-VIA semiconductor material is selected from one or more of ZnS, ZnSe and CdS. The IIIA-VA semiconductor material is selected from one or more of InP and GaP. The IB-IIIA-VIA family semiconductor material is selected from one or more of CuInS and CuGaS.

In some embodiments, the p-type semiconductor nanoparticle is selected from one or more of second doped metal oxide particle, second undoped metal oxide particle, metal sulfide, metal selenide and metal nitride. A metal oxide in the second doped metal oxide particle and a metal oxide in the second undoped metal oxide particle is independently selected from one or more of MoO₃, WO₃, NiO, CrO₃, CuO, Cu₂O and V₂O₅. A doping element in the second doped metal oxide particle is selected from one or more of Mo, W, Ni, Cr, Cu and V. The metal sulfide is selected from one or more of CuS, MoS₃ and WS₃. The metal selenide is selected from one or more of MoSe₃ and WSe₃. The metal nitride is selected from p-type gallium nitride.

In some embodiments, 1≤X≤12, which can be 2, 3, 4, 5, 6, 7, 8, 9, 10, 11, etc.

In some embodiments, 1≤Y≤13, which can be 2, 3, 4, 5, 6, 7, 8, 9, 10, 11, 12, etc.

When the inorganic nanoparticle is selected from the quantum dot, 1≤X≤12 and 1≤Y ≤13.

When the inorganic nanoparticle is selected from the n-type semiconductor nanoparticle or the p-type semiconductor nanoparticle, 1≤X≤10 and 1≤Y≤11.

In this way, within the range of the above values of X and Y, it is beneficial for the first film 11 and the second film 12 to jointly improve the bending resistance of the composite film 10 composite film 10 and ensure the conductivity of the composite film 10.

In some embodiments, when the inorganic nanoparticle is selected from the quantum dot, a sum of a thicknesses of the first film 11 ranges between 5 nm-60 nm, such as 10 nm, 20 nm, 30 nm, 40 nm, and 50 nm, etc. Within the thickness and range of the first film 11, the first film 11 has good luminous performance. In other words, the first film 11 may be a layer, and a thickness of the layer of the first film 11 may be 5 nm or 60 nm. The first film 11 may also be twelve layers, a sum of a thicknesses of the twelve layers of the first film 11 is 60 nm, and a thickness of each layer of the first film 11 is 5 nm.

In some embodiments, when the inorganic nanoparticle is selected from is selected from the n-type semiconductor nanoparticle or the p-type semiconductor nanoparticle, a sum of a thicknesses of the first film 11 ranges between 10 nm-100 nm, such as 20 nm, 30 nm, 40 nm, 50 nm, 60 nm, 70 nm, 80 nm, and 90 nm, etc. Within the thickness and range of the first film 11, a carrier transmission performance of the first film 11 is good. In other words, the first film 11 may be one layer, and a thickness of the layer of the first film 11 may be 10 nm or 100 nm. The first film 11 may also be ten layers, a sum of a thicknesses of the ten layers of the first film 11 is 100 nm, and a thickness of each layer of the first film 11 is 10 nm.

In some embodiments, a fracture toughness of the second film 12 ranges between 5 MPa·m^{0.5}-100 MPa·m^{0.5}, such as 10 MPa·m^{0.5}, 20 MPa·m^{0.5}, 30 MPa·m^{0.5}, 40 MPa·m^{0.5}, 50 MPa·m^{0.5}, 60 MPa·m^{0.5} and 70 MPa·m^{0.5}. Within the range of the second film 12, a toughness of the second film 12 is good, which can effectively improve the bending resistance of the composite film 10.

It can be understood that the inorganic metal compound contains metal, which can further improve the conductivity of the composite film 10.

In some embodiments, the inorganic metal compound is selected from one or more of the first II-VI compound, the first III-V compound, the first IV-IV compound, the IV-V compound, the V-V compound, the VI-V compound, the VI-VI compound and the VIII-V compound.

The first II-VI compound is selected from one or more of BaS, CaS, CdS, CdTe, Hg₁₋ₐCdₐTe, HgTe, MnTe, SrS, SrS_{1-b}Se_{b}, ZnS, ZnSe, ZnS_{1-c}Se_{c}, Cd_{1-d}Mn_{d}Te and ZnTe.

The first III-V compound is selected from one or more of AlAs, AlₑGa₁₋ₑAs, AlP, GaAs, Ga_{f}In_{1-f}As, GagIn_{1-g}P, GaP, InAs, InP, AlN, GaN and InN.

The first IV-IV compound includes TiC.

The IV-V compound is selected from one or more of TiN and SiNₕ.

The V-V compound includes NbN.

The VI-V compound includes MoN.

The VI-VI compound is selected from one or more of WS₂ and WS₃.

The VIII-V compound is selected from one or more of CoP and Co₂P.

Where a, b, c, d, e, f and g are all numbers greater than 0 and less than 1, and h is a number greater than or equal to 1 and less than or equal to 4 (1≤h≤4).

In some embodiments, the first film 11 is prepared by a solution method.

In some embodiments, the second film 12 is prepared by atomic layer deposition.

It should be noted that when the material of the first film 11 includes a second III-V compound, such as GaP, and the material of the second film 12 includes a first III-V compound, such as GaP, the first film 11 and the second film 12 are different. The GaP quantum dot in the first film 11 is nanoparticle formed by chemical synthesis, and the first film 11 is a film formed by stacking nanoparticles. While the GaP in the second film 12 is a conventional inorganic compound material, and the second film 12 is a dense film.

In some embodiments, a thickness of the second film 12 ranges between 1 nm-3 nm, such as 1.2 nm, 1.5 nm, 1.8 nm, 2 nm, 2.2 nm, 2.5 nm, and 2.8 nm, etc. Within the range of the second film 12, the second film 12 will not affect tunneling of carriers.

In some embodiments, a thickness of the composite film 10 ranges between 6 nm-133 nm, such as 10 nm, 20 nm, 40 nm, 50 nm, 60 nm, 80 nm, 100 nm, and 120 nm, etc.

In some embodiments, when the inorganic nanoparticle is selected from the quantum dot, a thickness of the composite film 10 ranges between 6 nm-99 nm, such as 10 nm, 20 nm, 30 nm, 40 nm, 50 nm, 60 nm, and 80 nm, etc.

In some embodiments, when the inorganic nanoparticle is selected from the n-type semiconductor nanoparticle or the p-type semiconductor nanoparticle, a thickness of the composite film 10 ranges between 11 nm-133 nm, such as 20 nm, 30 nm, 40 nm, 50 nm, 60 nm, 80 nm, 100 nm, and 120 nm, etc.

In some embodiments, adjacent the inorganic nanoparticle and the inorganic metal compound are connected by one or more of physical adsorption and chemical bond. The chemical bond includes covalent bond.

For example, a metal element in the inorganic metal compound form the covalent bond with a nonmetallic element in the inorganic nanoparticle. For example, when the inorganic metal compound is TiC and the inorganic nanoparticle is ZnO, the Ti atom can be connected with the O atom through the covalent bond.

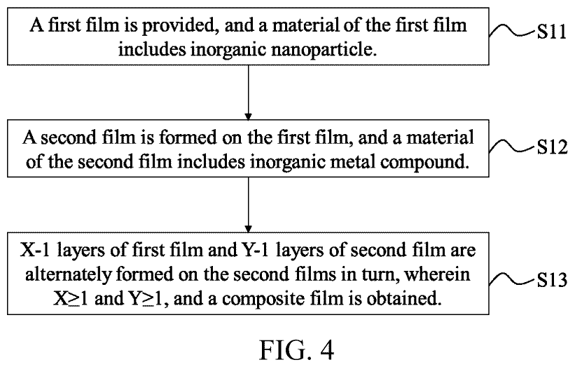

Referring to FIG. 4, the present disclosure proposes a preparation method of a composite film which includes steps S11-S13.

In step S11, a first film 11 is provided. A material of the first film 11 includes inorganic nanoparticle.

In step S12, a second film 12 is formed on the first film 11. A material of the second film 12 includes inorganic metal compound.

In step S13, X-1 layers of first film 11 and Y-1 layers of second film 12 are alternately formed on the second films 12 in turn, wherein X≥1 and Y≥1, and a composite film 10 is obtained.

It can be understood that the first film 11 can be prepared first, or the second film 12 can be prepared first.

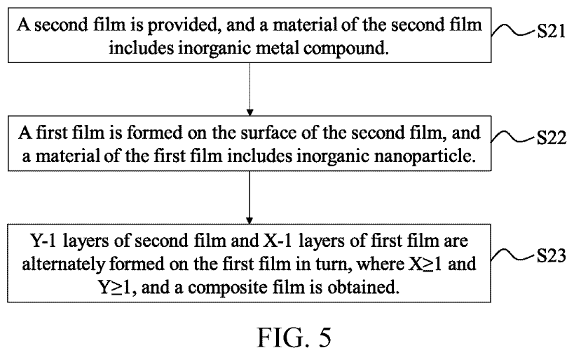

In other embodiments, referring to FIG. 5, the present disclosure proposes another preparation method of a composite film which includes steps S21-S23.

In step S21, a second film 12 is provided. A material of the second film 12 includes inorganic metal compound.

In step S22, a first film 11 is formed on the surface of the second film 12. A material of the first film 11 includes inorganic nanoparticle.

In step S23, Y-1 layers of second film 12 and X-1 layers of first film 11 are alternately formed on the first film 11 in turn, where X≥1 and Y≥1, and a composite film 10 is obtained.

In some embodiments, a forming method of the first film 11 can be realized by conventional techniques in the field, such as chemical method or physical method. The chemical method includes chemical vapor deposition, continuous ion layer adsorption and reaction, anodic oxidation, electrolytic deposition or coprecipitation. The physical method includes physical coating method and solution method. The physical coating method includes thermal evaporation coating method, electron beam evaporation coating method, magnetron sputtering method, multi-arc ion coating method, physical vapor deposition method, atomic layer deposition method or pulsed laser deposition method. The solution method includes spin coating method, printing method, ink-jet printing method, scraping method, printing method, dipping and pulling method, soaking method, spraying method, roller coating method, casting method, slit coating method or strip coating method, etc.

A forming method of the first film 11 includes a solution method.

In some embodiments, a method of forming the second film 12 includes atomic layer deposition (ALD). It can be understood that the deposition method of ALD can ensure the controllability of the thickness of the second film 12 and its compactness. At the same time, the deposition method is conformal and can ensure the maximum contact area between the second film 12 and the inorganic nanoparticle.

The atomic layer deposition includes introducing a cationic precursor and an anionic precursor to form the second thin film 12.

It should be noted that both the cationic precursor and the anionic precursor are gases.

In some embodiments, the cationic precursor is selected from one or more of Sr precursor, Ba precursor, Y precursor, Ti precursor, Nb precursor, Ta precursor, Mo precursor, W precursor, Mn precursor, Co precursor, Ni precursor, Zn precursor, Cd precursor, Hg precursor, Al precursor, Ga precursor, In precursor, Sn precursor and Sb precursor.

The Sr precursor is selected from strontium diisobutyrate (Sr(tmhd)₂).

The Ba precursor is selected from barium diisobutyrate (Ba(tmhd)₂).

The Y precursor is selected from yttrium triisobutyrate (Y(thd)₃).

The Ti precursor is selected from one or more of tetra(dimethylamino) titanium (IV) and titanium tetrachloride (TiCl₄).

The Nb precursor is selected from niobium pentachloride (NbCl₅).

The Ta precursor is selected from tantalum pentachloride (TaCl₅).

The Mo precursor is selected from molybdenum hexafluoride (MoF₆).

The W precursor is selected from tungsten hexafluoride (WF₆).

The Mn precursor is selected from manganese triisobutyrate (Mn(tmhd)₃).

The Co precursor is selected from one or more of cobalt triphosphate (Co(acac)₃) and cobaltocene (Cp₂Co).

The Ni precursor is selected from nickel metallocene (Cp₂Ni).

The Zn precursor is selected from diethyl zinc (DEZn).

The Cd precursor is selected from cadmium pyruvate (Cd(acac)₂).

The Hg precursor is selected from mercury difluoro pyruvate (Hg(hfac)₂).

The Al precursor is selected from trimethyl aluminum (TMA).

The Ga precursor is selected from trimethyl gallium (TMI).

The In precursor is selected from indium cyclopentadiene (Cp₂In).

The Sn precursor is selected from tetra-dimethylaminotin (TDMASn).

The Sb precursor is selected from antimony trichloride (SbCl₃).

In some embodiments, the anion precursor is selected from one or more of C precursor, N precursor, P precursor, As precursor, O precursor, S precursor, Se precursor, Te precursor and F precursor.

The C precursor is selected from methane (CH₄).

The N precursor is selected from ammonia gas (NH₃).

The P precursor is selected from one or more of phosphine (PH₃) and trialkylphosphine.

The As precursor is selected from hydrogen arsenide (AsH₃).

The O precursor is selected from ozone (O₃).

The S precursor is selected from hydrogen sulfide (H₂S).

The Se precursor is selected from hydrogen selenide (H₂Se).

The Te precursor is selected from tellurium tetrachloride (TeCl₄).

The F precursor is selected from nitrogen trifluoride (NF₃).

In some embodiments, the introducing a cationic precursor and an anionic precursor is carried out in an inert atmosphere. An inert gas in the inert atmosphere is selected from one or more of helium, neon, argon, krypton, xenon and nitrogen.

In some embodiments, the introducing a cationic precursor and an anionic precursor is carried out in a heated atmosphere. A temperature of the heated atmosphere ranges between 100° C.-300° C., such as 120° C., 150° C., 180° C., 200° C., 220° C., 250° C., and 280° C., etc. Within the range of the temperature, it is beneficial to promote the reaction rate of the cationic precursor and the anionic precursor to generate inorganic metal compound.

In some embodiments, the introducing a cationic precursor and an anionic precursor is carried out in a vacuum atmosphere. A vacuum degree of the vacuum atmosphere ranges between 0.001 Torr-0.1 Torr, such as 0.01 Torr, 0.02 Torr, 0.04 Torr, 0.05 Torr, 0.06 Torr, 0.08 Torr, and 0.09 Torr, etc. Within the range of the vacuum degree, it is beneficial to improve a yield of inorganic metal compound generated by the reaction between the cationic precursor and the anionic precursor.

In some embodiments, the introducing a cationic precursor and an anionic precursor includes: introducing the cationic precursor first and then introducing the anionic precursor. It can be understood that the cationic precursor can bond with the inorganic nanoparticle to promote the close contact between the first film 11 and the second film 12, and then the anionic precursor reacts with the cationic precursor to form a dense second film 12.

In some embodiments, a time for introducing the cationic precursor and the anionic precursor independently ranges between 0.01 s-0.5 s, such as 0.05 s, 0.1 s, 0.2 s, 0.3 s, and 0.4 s, etc.

In some embodiments, after introducing the cationic precursor, and before introducing the anionic precursor, it also includes introducing clean gas. It can be understood that the cleaning gas can clean the gas atmosphere.

The cleaning gas is selected from one or more of helium, neon, argon, krypton, xenon and nitrogen. A time for introducing the clean gas ranges between 5 s-15 s, such as 7 s, 9 s, 11 s, and 13 s, etc.

In some embodiments, after introducing the cationic precursor and the anionic precursor, the cationic precursor and the anionic precursor are recycled introducing to form the second film 12.

A time of recycling introducing the cationic precursor and the anionic precursor ranges between 2-8 times, such as 2 times, 3 times, 5 times, and 7 times, etc.

It can be understood that X=Y+x, and x is 0 or 1. When X=Y=1, that is, the composite film 10 includes a first film 11 and a second film 12.

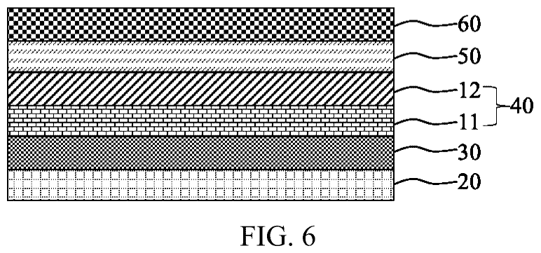

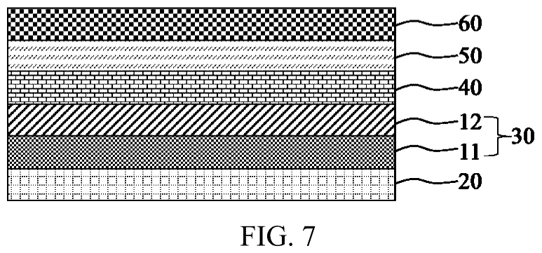

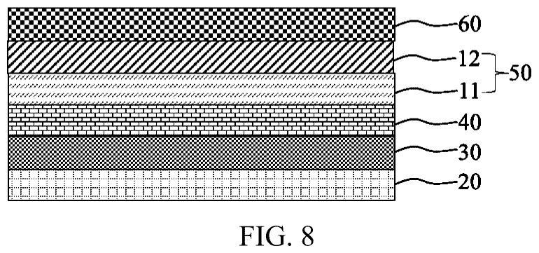

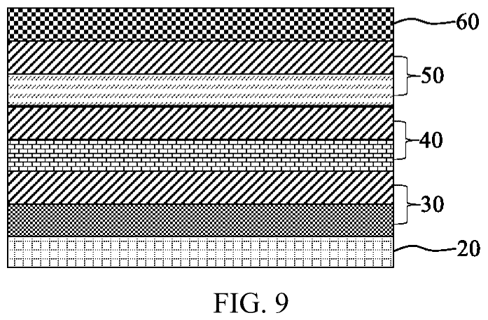

Referring to FIG. 6, FIG. 7, FIG. 8 and FIG. 9, the present disclosure discloses a light-emitting device, including:
an anode 20;
a functional layer, located on the anode 20; and
a cathode 60, located on the functional layer;
wherein the functional layer includes the composite film 10.

In some embodiments, the light-emitting device comprises a light-emitting diode.

It can be understood that the light-emitting device can be an upright light-emitting device or an inverted light-emitting device.

In some embodiments, the functional layer sequentially includes one or more of a hole functional layer 30, an active layer 40, and an electronic functional layer 50 along the anode 20 to the cathode 60. One or more of the hole functional layer 30, the active layer 40, and the electronic functional layer 50 includes the composite film 10.

The hole functional layer 30 includes one or more of a hole injection layer and a hole transport layer.

The electronic functional layer 50 includes one or more of an electronic injection layer and an electronic transport layer.

In some embodiments, referring to FIG. 6, when the active layer 40 includes the composite film 10, a material of the first film 11 includes the quantum dot. When at least one of the hole functional layer 30 and the electronic functional layer 50 includes the composite film 10, a material of the active layer 40 includes a luminescent material, and the luminescent material is selected from an organic luminescent material or the quantum dot.

A material of the organic luminescent is selected from one or more of CBP:Ir(mppy)₃(4,4′-bis(N-carbazole)-1,1′-biphenyl:tris [2-(p-tolyl)pyridine iridium (III)]), TCTX:Ir(mmpy)(4,4′), 4″-tris(carbazole-9-yl)triphenylamine: tris [2-(p-tolyl) iridium pyridine]), diarylanthracene derivatives, stilbene aromatic derivatives, pyrene derivatives, fluorene derivatives, TBPe fluorescent materials, TTPX fluorescent materials, TBRb fluorescent materials, DBP fluorescent materials, delayed fluorescent materials, TTA materials, TADF (delayed thermal activation) materials, polymers containing B—N covalent bonds, HLCT (hybrid local charge transfer excited state) materials and Exciplex luminescent materials.

In some embodiments, referring to FIG. 7. When the hole functional layer 30 includes the composite film 10, a material of the first film 11 includes the p-type semiconductor nanoparticle. When at least one of the active layer 40 and the electronic functional layer 50 includes the composite film 10, a material of the hole functional layer 30 is selected from one or more of the p-type semiconductor nanoparticle, 4,4′-N,N′-dicarbazolyl-biphenyl, N,N′-diphenyl-N,N′-bis (1-naphthyl)-1,l′-biphenyl)-4,4′-diamine, N,N′-bis(3-methylphenyl)-N,N′-bis (phenyl)-spiro, N,N′-bis(4-(N,N′-diphenyl-amino)phenyl)-N,N′-diphenylbenzidine, 4,4′, 4′-tris (N-carbazolyl)-triphenylamine, 4,4′, 4′-tris (carbazole-9-yl)triphenylamine, trichloroisocyanuric acid, terbium-doped phosphate-based green luminescent material, 2,3,6,7,10,11-hexacyano-1,4,5,8,9,12-hexaazaphenanthrene, 4,4′, 4′-tris (N-3-methylphenyl-N-phenylamino) triphenylamine, poly [(9,9′-dioctyl fluorene-2,7-diyl)-co-(4, 4′-(N-(4-sec-butylphenyl) diphenylamine))], poly (4-butylphenyl-diphenylamine), poly [bis(4-phenyl) (4-butylphenyl)amine], polyaniline, polypyrrole, poly (p)phenylene vinylene, poly (phenylene vinylene), poly [2-methoxy-5-(2-ethylhexyloxy)-1,4-phenylene vinylene], poly [2-methoxy-5-(3′, 7′-dimethyl octyloxy)-1,4-phenylene vinylene], copper phthalocyanine, aromatic tertiary amine, 4,4′-bis (p-carbazolyl)-1,l′-biphenyl compound, N,N,N′,N′-tetraarylbenzidine, PEDOT, PEDOT: PSS and its derivatives, PEDOT: PSS derivatives doped with s-MoO₃, poly (N-vinylcarbazole) and its derivatives, polymethacrylate and its derivatives, poly (9,9-octylfluorene) and its derivatives, poly (spirofluorene) and its derivatives, N,N′-bis (naphthalene-1-yl)-N,N′-diphenylbenzidine, spiro NPB, nano-polycrystalline diamond, microcrystalline cellulose, tetracyanoquinone dimethylmethane, doped graphene and undoped graphene.

In some embodiments, referring to FIG. 8, when the electronic functional layer 50 includes the composite film 10, a material of the first film 11 includes n-type semiconductor nanoparticle. When at least one of the active layer 40 and the hole functional layer 30 includes the composite film 10, a material of the electronic functional layer 50 is selected from the n-type semiconductor nanoparticle.

In some embodiments, a material of the anode 20 and the cathode 60 is each independently selected from one or more of metal, carbon material and metal oxide. The metal is selected from one or more of Al, Ag, Cu, Mo, Au, Ba, Ca, Yb and Mg. The carbon material is selected from one or more of graphite, carbon nanotubes, graphene and carbon fiber. The metal oxide is selected from one or more of metal oxide electrode or composite electrode with metal sandwiched between doped or undoped transparent metal oxide, and a material of the metal oxide electrode is selected from one or more of ITO, FTO, ATO, AZO, GZO, IZO, MZO, MoOs and AMO. The composite electrode is selected from one or more of AZO/Ag/AZO, AZO/AVAZO, ITO/Ag/ITO, ITO/AI/ITO, ZnO/Ag/ZnO, ZnO/Al/ZnO, ZnS/Ag/ZnS, ZnS/Al/ZnS, TiO₂/Ag/TiO₂ and TiO₂/Al/TiO₂. Where “/” represents a laminated structure, for example, AZO/Ag/AZO represents a composite electrode including an AZO layer, an Ag layer and an AZO layer which are sequentially laminated.

The present disclosure also discloses a display device, including the light-emitting device in any of the above embodiments.

The display device can be a mobile terminal such as a TV set, a mobile phone, a tablet computer, a computer monitor, or a device with a display screen such as a game device, an Augmented Reality (AR) device, a Virtual Reality (VR) device, a data storage device, an audio playback device, a video playback device, and a wearable device, wherein the wearable device can be a smart bracelet, smart glasses, and a smart watch.

This present disclosure will be explained in detail by specific examples. The following examples are only partial examples of this present disclosure, and are not limited to this present disclosure.

### Example 1

This example provides a composite film, which includes a CdZnSe film (first film) and a TiN film (second film) which are arranged in cascade, and a preparation method of the composite film includes steps S1-S2.

In step S1, a substrate is provided, and a 10 mg/mL CdZnSe solution is spin-coated on the substrate at a rotational speed of 2000 rpm for 30 seconds to form a CdZnSe film.

In step S2, the first film of CdZnSe is placed in ALD equipment, and 0.1 s tetra (dimethylamino) titanium is introduced at the chamber temperature of 200° C. and the vacuum degree is not higher than 0.1 Torr. Then nitrogen gas is introduced for 5 seconds to clean the gas atmosphere, ammonia gas is introduced for 0.1 second, and nitrogen gas is introduced for 5 seconds to clean. The cycle is repeated for 6 times to form a TiN film with a thickness of 2 nm, and a composite film is obtained.

### Example 2

This example is basically the same as Example 1, only the difference is that in this example, ammonia gas is replaced by methane, and the second film is TiC film.

### Example 3

This example is basically the same as Example 1, only the difference is that in this example, tetra(dimethylamino) titanium is replaced by tungsten hexafluoride, and ammonia gas is replaced by hydrogen sulfide, and the second film is WS₂ film.

### Example 4

This example is basically the same as Example 1, only the difference is that in this example, tetra(dimethylamino) titanium is replaced by cobaltocene, and ammonia gas is replaced by trialkylphosphine, and the second film is CoP film.

### Example 5

This example is basically the same as Example 1, only the difference is that in this example, a thickness of the TiN second film is 3 nm.

### Example 6

This example is basically the same as Example 1, only the difference is that in this example, a thickness of the TiN second film is 1 nm.

### Example 7

This example is basically the same as Example 1, only the difference is that in this example, CdZnSe is replaced by core-shell quantum dot ZnSe/ZnS.

### Example 8

This example is basically the same as Example 1, only the difference is that in this example, CdZnSe is replaced by n-type semiconductor material ZnO, and the first film is ZnO film.

### Example 9

This example is basically the same as Example 8, only the difference is that in this example, tetra(dimethylamino) titanium is replaced by niobium pentachloride, and the second film is NbN film.

### Example 10

This example is basically the same as Example 8, only the difference is that in this example, tetra(dimethylamino) titanium is replaced by diethyl zinc, and ammonia gas is replaced by hydrogen selenide, and the second film is ZnSe film.

### Example 11

This example is basically the same as Example 1, only the difference is that in this example, CdZnSe is replaced by p-type semiconductor material NiO, and the first film is NiO film.

### Example 12

This example is basically the same as Example 11, only the difference is that in this example, tetra(dimethylamino) titanium is replaced by molybdenum hexafluoride, and the second film is MON film.

### Example 13

This example is basically the same as Example 11, only the difference is that in this example, tetra(dimethylamino) titanium is replaced by trimethyl aluminum, and ammonia gas is replaced by phosphine, and the second film is AlP film.

### Example 14

This example is basically the same as Example 1, only the difference is that in this example, after the TiN film is formed, another CdZnSe film is formed on the TiN film. The composite film includes a CdZnSe film, a TiN film and a CdZnSe film which are sequentially stacked.

### Example 15

This example is basically the same as Example 1, only the difference is that in this example, a TiN film is formed first, and then a CdZnSe film and another TiN film are formed in turn. The composite film includes a TiN film, a CdZnSe film and a TiN film which are sequentially stacked.

### Comparative Example 1

This comparative example is basically the same as Example 1, only the difference is that in this comparative example, the film only includes the CdZnSe film (first film).

### Comparative Example 2

This comparative example is basically the same as Example 1, only the difference is that in this comparative example, a thickness of the TiN second film is 10 nm.

### Comparative Example 3

This comparative example is basically the same as Example 1, only the difference is that in this comparative example, a thickness of the TiN second film is 0.7 nm.

### Comparative Example 4

This comparative example is basically the same as Example 8, only the difference is that in this comparative example, the film only includes the ZnO film (first film).

### Comparative Example 5

This comparative example is basically the same as Example 11, only the difference is that in this comparative example, the film only includes the NiO film (first film).

### Performance Test:

The fracture toughness of composite films in Examples 1-15 and films of Comparative Examples 1-5 were tested, and the results are shown in Table 1. Among them, the fracture toughness was tested according to JBT 12721-2016 technical specification of in-situ nano-indentation scratch tester for solid materials, and the fracture toughness was calculated according to Vickers hardness value.

TABLE 1

| | Fracture toughness |
|---|---|
| | (MPa · m^{0.5}) |
| Example 1 | 12.5 |
| Example 2 | 15.9 |
| Example 3 | 14.4 |
| Example 4 | 10.6 |
| Example 5 | 12.5 |
| Example 6 | 12.5 |
| Example 7 | 12.5 |
| Example 8 | 12.5 |
| Example 9 | 10.7 |
| Example 10 | 11.4 |
| Example 11 | 12.5 |
| Example 12 | 11.7 |
| Example 13 | 10.5 |
| Example 14 | 12.5 |
| Example 15 | 12.5 |
| Comparative Example 1 | 1.3 |
| Comparative Example 2 | 21.5 |
| Comparative Example 3 | 5.1 |
| Comparative Example 4 | 2.0 |
| Comparative Example 5 | 1.9 |

It can be seen from examples 1-7 and comparative examples 1-3 that when a material of the first film is quantum dot, the inorganic metal compound can effectively improve the fracture toughness of the composite film, whether it is single-structure quantum dot or core-shell quantum dot. The improvement effect of inorganic metal compound on the fracture toughness of composite film is influenced by their own fracture toughness. Within the thickness range of the second film provided in this application, the thickness of the second film has little effect on the fracture toughness of the composite film.

From examples 8-10 and comparative example 4, it can be seen that when a material of the first film is n-type semiconductor nanoparticle, the second film formed by inorganic metal compound can still effectively improve the fracture toughness of the composite film.

From examples 11 to 13 and comparative example 5, it can be seen that when a material of the first film is p-type semiconductor nanoparticle, the second film formed by inorganic metal compound can still effectively improve the fracture toughness of the composite film.

From examples 1, 14-15 and comparative example 1, it can be seen that the fracture toughness of composite films can be effectively improved in both the first film/second film structure and the first film/second film/first film and second film/first film/second film structure compared with comparative example 1.

### Light-Emitting Device Example 1

This example provides a light-emitting device, and a preparation method of the light-emitting device includes steps S3-S9.

In step S3, an ITO glass is provided, and the surface of the ITO glass is wiped with a cotton swab dipped in a small amount of soapy water to remove impurities visible to the naked eye. Then, it is ultrasonically cleaned with deionized water, acetone, ethanol and isopropanol for 15 min, dried with nitrogen and irradiated with UV for 15 min to form ITO anode.

In step S4, a PEDOT: PSS is spin-coated on the ITO anode at the rotating speed of 5000 rpm for 30 s, and then heated at 150° C. for 15 min to form a hole injection layer.

In step S5, a TFB is dissolved in chlorobenzene at a concentration of 8 mg/mL, and then it is spin-coated on the hole injection layer at a rotation speed of 3000 rpm for 30 s, followed by UV irradiation for 10 min and heating at 200° C. for 10 min to form a hole transport layer.

In step S6, a composite film is formed on the hole transport layer according to the method of Example 1, and a luminescent layer is obtained.

In step S7, a ZnO is spin-coated on the luminescent layer, and the spin-coating speed was 3000 rpm for 30 s, followed by heating at 80° C. for 30 min to form an electronic transport layer.

In step S8, an Ag was evaporated by thermal evaporation on the electronic transport layer, vacuum degree is not higher than 3×10⁻⁴ Pa, the speed is 1 Å/s, the time is 1000 s, and a cathode with a thickness of 100 nm is obtained.

In step S9, a light-emitting device is obtained after packaging.

### Light-Emitting Device Examples 2-7

Light-emitting device Examples 2-7 are basically the same as light-emitting device Example 1, and only the difference is that the composite film of Example 1 is replaced by the composite film of Examples 2-7, respectively, to obtain light-emitting devices.

### Light-Emitting Device Examples 8-10

Light-emitting device Examples 8-10 are basically the same as light-emitting device Example 1, and only the difference is that the luminescent layer is prepared according to the method of Comparative Example 1, and the electronic transport layer is prepared according to the preparation methods of Examples 8 to 10, respectively, to obtain light-emitting devices.

### Light-Emitting Device Examples 11-13

Light-emitting device Examples 11-13 are basically the same as light-emitting device Example 1, and only the difference is that the luminescent layer is prepared according to the method of Comparative Example 1, and the hole transport layer is prepared according to the preparation methods of Examples 11 to 13, respectively, to obtain light-emitting devices.

### Light-Emitting Device Example 14

This Light-emitting device Example is basically the same as light-emitting device Example 1, and only the difference is that the composite film of Example 1 is replaced by the composite film of Example 14, to obtain light-emitting device.

### Light-Emitting Device Example 15

This Light-emitting device Example is basically the same as light-emitting device Example 1, and only the difference is that the electronic transport layer is prepared according to the preparation method of Example 8, and the hole transport layer is prepared according to the preparation method of Example 11, to obtain light-emitting device.

### Light-Emitting Device Comparative Examples 1-3

Light-emitting device Comparative Examples 1-3 are basically the same as light-emitting device Example 1, and only the difference is that the composite film of Example 1 is replaced by the composite film or film of Comparative Examples 1-3, respectively, to obtain light-emitting devices.

### Light-Emitting Device Comparative Example 4

This Light-emitting device Comparative Example is basically the same as light-emitting device Example 8, and only the difference is that the composite film of Example 8 is replaced by the film of Comparative Example 4, to obtain light-emitting device.

### Light-Emitting Device Comparative Example 3

This Light-emitting device Comparative Example is basically the same as light-emitting device Example 11, and only the difference is that the composite film of Example 11 is replaced by the film of Comparative Example 5, to obtain light-emitting device.

### Performance Test:

The maximum brightness (Lₘₐₓ) and measured lifetime T95 of the light-emitting devices in Light-emitting device Examples 1-15 and Light-emitting device Comparative Examples 1-5 were tested respectively. The result obtained are shown in Table 2.

The maximum brightness (Lₘₐₓ) is tested by a brightness meter. The test method of the measured life T95 is as follows: when the device is driven by constant current or voltage, the time required for the brightness to decrease to a certain proportion of the highest brightness, and the time for the brightness to decrease to 95% of the highest brightness is defined as T95, which is the measured life. In order to shorten the test period, the device life test is usually carried out by accelerating the device aging under high brightness. The specific calculation formula is as follows:

$$T {95}_{L} = T {95}_{H} \cdot {( \frac{{L}_{H}}{{L}_{L}} )}^{A}$$

Among them, T95_{L} is the lifetime under low brightness, T95_{H} is the measured lifetime under high brightness, L_{H} is the acceleration of the device to the highest brightness, L_{L} is 1000 nit, and A is the acceleration factor. In this experiment, a value of 1.7 is obtained by measuring the lifetime of several groups of QLED devices under rated brightness.

TABLE 2

| | Lₘₐₓ | T95 |
|---|---|---|
| | (nit) | (h) |
| Light-emitting device Example 1 | 7122 | 25.1 |
| Light-emitting device Example 2 | 7051 | 25.6 |
| Light-emitting device Example 3 | 7189 | 24.4 |
| Light-emitting device Example 4 | 7994 | 24.2 |
| Light-emitting device Example 5 | 7003 | 24.9 |
| Light-emitting device Example 6 | 7101 | 24.5 |
| Light-emitting device Example 7 | 8123 | 31.6 |
| Light-emitting device Example 8 | 7176 | 24.8 |
| Light-emitting device Example 9 | 7111 | 24.9 |
| Light-emitting device Example 10 | 7167 | 24.6 |
| Light-emitting device Example 11 | 5324 | 12.5 |
| Light-emitting device Example 12 | 5421 | 13.1 |
| Light-emitting device Example 13 | 5386 | 12.8 |
| Light-emitting device Example 14 | 7152 | 23.4 |
| Light-emitting device Example 15 | 7187 | 24.0 |
| Comparative Light-emitting device Example 1 | 7031 | 24.7 |
| Comparative Light-emitting device Example 2 | 1128 | 6.2 |
| Comparative Light-emitting device Example 3 | 7014 | 24.5 |
| Comparative Light-emitting device Example 4 | 7031 | 24.7 |
| Comparative Light-emitting device Example 5 | 5322 | 12.7 |

From the light-emitting device examples 1-7 and light-emitting device comparative examples 1-3, it can be seen that the performance of light-emitting devices with the light-emitting layer containing the core-shell quantum dot is better than that of single-structure quantum dot. After adding the second film of inorganic metal compound, the light-emitting device examples 1-4 and 6-7 have certain improvement effects compared with the light-emitting device comparative examples 1-3. A thickness of the inorganic metal compound in light-emitting device example 5 is relatively thick, which will affect the performance of the light-emitting device to some extent. In light-emitting device comparative example 2, a thickness of the second film was too thick, which affected the normal performance of the luminescent layer, resulting in a sharp decline in brightness and service life.

According to the light-emitting device examples 8-10 and the light-emitting device comparative example 4, when a material of the first film is n-type semiconductor nanoparticle, that is, when the first film is an electronic transport layer, the brightness and service life of the light-emitting device examples 8-10 with the second film are obviously improved compared with the light-emitting device comparative example 4.

According to the light-emitting device examples 11-13 and the light-emitting device comparative example 5, when a material of the first thin film is p-type semiconductor nanoparticle, that is, when the first film is a hole transport layer, compared with the light-emitting device comparative example 5, the light-emitting device examples 11-13 with the second film have obviously improved the brightness and service life of the light-emitting devices.

From the light-emitting device examples 1, 14-15 and the light-emitting device comparative example 1, it can be seen that the alternating arrangement structure of the first film and the second film has a slight improvement effect on the performance of the light-emitting device compared with the light-emitting device comparative example 1.

The lifetimes of the light-emitting devices of Light-emitting device Examples 1-15 and Light-emitting device Comparative examples 1-5 after bending for 20,000 times, 50,000 times and 150,000 times were tested respectively, and the percentage of life loss was calculated, and the results are shown in Table 3.

TABLE 3

| | Life loss after | Life loss after | Life loss after |
|---|---|---|---|
| | bending for | bending for | bending for |
| | 20,000 times (%) | 50,000 times (%) | 150,000 times (%) |
| Light-emitting device | 3.5 | 6.6 | 10.5 |
| Example 1 | | | |
| Light-emitting device | 2.6 | 5.5 | 8.9 |
| Example 2 | | | |
| Light-emitting device | 3.6 | 5.2 | 9.1 |
| Example 3 | | | |
| Light-emitting device | 4.1 | 7.2 | 12.4 |
| Example 4 | | | |
| Light-emitting device | 3.6 | 6.5 | 10.4 |
| Example 5 | | | |
| Light-emitting device | 3.7 | 6.8 | 10.9 |
| Example 6 | | | |
| Light-emitting device | 3.4 | 6.6 | 10.6 |
| Example 7 | | | |
| Light-emitting device | 3.3 | 6.2 | 9.9 |
| Example 8 | | | |
| Light-emitting device | 4.0 | 7.1 | 12.3 |
| Example 9 | | | |
| Light-emitting device | 3.9 | 5.8 | 11.9 |
| Example 10 | | | |
| Light-emitting device | 3.3 | 6.1 | 9.3 |
| Example 11 | | | |
| Light-emitting device | 3.8 | 5.6 | 11.5 |
| Example 12 | | | |
| Light-emitting device | 4.2 | 7.4 | 12.6 |
| Example 13 | | | |
| Light-emitting device | 3.4 | 6.4 | 10.2 |
| Example 14 | | | |
| Light-emitting device | 3.1 | 6.2 | 9.9 |
| Example 15 | | | |
| Light-emitting device | 20.1 | 41.5 | 75.2 |
| Comparative Example 1 | | | |
| Light-emitting device | 1.2 | 3.2 | 4.4 |
| Comparative Example 2 | | | |
| Light-emitting device | 15.2 | 32.5 | 60.7 |
| Comparative Example 3 | | | |
| Light-emitting device | 20.1 | 41.5 | 75.2 |
| Comparative Example 4 | | | |
| Light-emitting device | 28.4 | 56.2 | 81.2 |
| Comparative Example 5 | | | |

From the light-emitting device examples 1-7 and light-emitting device comparative examples 1-3, it can be seen that the performance of light-emitting devices with the light-emitting layer containing the core-shell quantum dot is better than that of single-structure quantum dot. After adding the second film of inorganic metal compound, the light-emitting device examples 1-4 and 6-7 have certain improvement effects compared with the light-emitting device comparative examples 1-3. A thickness of the inorganic metal compound in light-emitting device example 5 is relatively thick, which will affect the performance of the light-emitting device to some extent. In light-emitting device comparative example 2, a thickness of the second film was too thick, which affected the normal performance of the luminescent layer, resulting in a sharp decline in brightness and service life.

According to the light-emitting device examples 1-7 and the light-emitting device comparative examples 1-3, in the light-emitting device comparative example 1, after bending, the life of the light-emitting device drops sharply, and even drops by 60.7% after bending for 150,000 times, which is difficult to meet the requirements of flexible light-emitting devices. In this application, the second film formed by adding inorganic metal compound significantly reduces the life loss after bending. The life loss after bending for 20,000 times does not exceed 5%, the life loss after bending for 50,000 times does not exceed 10%, and the life loss after bending for 150,000 times does not exceed 15%, which shows that the bending resistance of the composite film provided by this application has been obviously improved.

From the light-emitting device examples 8-10 and the light-emitting device comparative example 4, it can be seen that inorganic metal compound is also very effective in improving the bending resistance of the electronic transport layer, and there is no significant difference in the bending resistance between the light-emitting device examples 8-10 and the light-emitting device example 1, which can meet the requirements of flexible light-emitting devices.

From the light-emitting device examples 11-13 and the light-emitting device comparative example 5, it can be seen that inorganic metal compound is also very effective in improving the bending resistance of the hole transport layer, and there is no significant difference in bending resistance between the light-emitting device examples 11-13 and the light-emitting device example 1, which can meet the requirements of flexible light-emitting devices.

According to the light-emitting device examples 1, 14-15 and the light-emitting device comparative example 1, in the light-emitting device, the second film formed by the inorganic metal compound arranged adjacent to the carrier functional layer and/or the light-emitting layer can effectively improve the bending resistance of the composite film, thereby reducing the life loss of the light-emitting device after bending and prolonging the service life of the light-emitting devices.

Composite film, preparation method thereof and light-emitting device are described in detail above. The principles and embodiments of the present disclosure have been described with reference to specific embodiments, and the description of the above embodiments is merely intended to aid in the understanding of the method of the present disclosure and its core idea. At the same time, changes may be made by those skilled in the art to both the specific implementations and the scope of present disclosure in accordance with the teachings of the present disclosure. In view of the foregoing, the content of the present specification should not be construed as limiting the disclosure.

What is claimed is:

1. A composite film, comprising:
X layers of first film; and
Y layers of second film alternately stacked with X layers of the first film;
wherein X is an integer ≥1 and Y is an integer ≥1, and a material of the first film comprises inorganic nanoparticle, and a material of the second film comprises inorganic metal compound.

2. The composite film according to claim 1, wherein a fracture toughness of the second film ranges between 5 MPa·m^{0.5}-100 MPa·m^{0.5};
a thickness of the second film ranges between 1 nm-3 nm; and
adjacent the inorganic nanoparticle and the inorganic metal compound are connected by one or more of physical adsorption and chemical bond, and the chemical bond comprises covalent bond.

3. The composite film according to claim 1, wherein X=Y+x, and x is 0 or 1, and 1≤X≤12 and 1≤Y≤13;
the inorganic nanoparticle is selected from one of quantum dot, n-type semiconductor nanoparticle and p-type semiconductor nanoparticle, and an average particle size of the inorganic nanoparticle ranges between 1 nm-20 nm; and
the inorganic metal compound is selected from one or more of the first II-VI compound, the first III-V compound, the first IV-IV compound, the IV-V compound, the V-V compound, the VI-V compound, the VI-VI compound and the VIII-V compound.

4. The composite film according to claim 3, wherein the inorganic nanoparticle is selected from the quantum dot;
a sum of a thicknesses of the first film ranges between 5 nm-60 nm;
a thickness of the composite film ranges between 6 nm-99 nm;
the quantum dot is selected from one or more of single-structure quantum dot, core-shell quantum dot and perovskite semiconductor material; a material of the single-structure quantum dot, a core material of the core-shell quantum dot and a shell material of the core-shell quantum dot can be respectively selected from but not limited to one or more of second II-VI compound, second IV-VI compound, second III-V compound and I-III-VI compound, and shell layer of the core-shell structure quantum dot comprises one or more layers, and the second II-VI compound is selected from one or more of CdS, CdSe, CdTe, ZnS, ZnSe, ZnTe, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe and HgZnSTe, and the second IV-VI compound is selected from one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe and SnPbSTe, and the second III-V compound is selected from one or more of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GalnNP, GalnNAs, GaInNSb, GalnPAs, GalnPSb, InAlNP, InAlNAs, InAlNSb, InAlPAs and InAlPSb, and the I-III-VI compound is selected from one or more of CuInS₂, CuInSe₂ and AglnS₂, and the core-shell quantum dot is selected from one or more of CdSe/CdSeS/CdS, InP/ZnSeS/ZnS, CdZnSe/ZnSe/ZnS, CdSe/ZnS, CdSe/ZnSe, ZnSe/ZnS, ZnSe/ZnS, ZnSe/ZnS, and ZnSe/ZnSe/ZnSe, and the perovskite semiconductor material is selected from one of doped or undoped inorganic perovskite semiconductor or organic-inorganic hybrid perovskite semiconductor, and a general structural formula of the inorganic perovskite semiconductor is AMZ₃, wherein A is Cs⁺, and M is divalent metal cation, which is selected from one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺ and Eu²⁺, and Z is a halogen anion selected from one or more of Cl⁻, Br⁻ and I⁻, and the general structural formula of the organic-inorganic hybrid perovskite semiconductor is BMZ₃, wherein B is an organic amine cation selected from CH₃(CH₂)ₙ₋₂NH₃⁺ or [NH₃(CH₂)ₙNH₃]²⁺, wherein n≥2, and M is a divalent metal cation selected from Pb²⁺, Sn²⁺, Cu²⁺, Ni²⁺, Cd²⁺ and Cr³⁺, and Z is a halogen anion selected from one or more of Cl⁻, Br⁻ and I⁻;
$$1 \leq X \leq 12 and 1 \leq Y \leq 13 ;$$
the first film is prepared by a solution method.

5. The composite film according to claim 3, wherein the inorganic nanoparticle is selected from the n-type semiconductor nanoparticle;
a sum of a thicknesses of the first film ranges between 10 nm-100 nm;
a thickness of the composite film ranges between 11 nm-133 nm;
the n-type semiconductor nanoparticle is selected from one or more of first doped metal oxide particle, first undoped metal oxide particle, IIB-VIA semiconductor material, IIIA-VA semiconductor material and IB-IIIA-VIA semiconductor material, and a material of the first undoped metal oxide particle is selected from one or more of ZnO, TiO₂, SnO₂, ZrO₂ and Ta₂O₅, and a metal oxide in the first doped metal oxide particle is selected from one or more of ZnO, TiO₂, SnO₂, ZrO₂, Ta₂O₅ and Al₂O₃, and a doping element in the first doped metal oxide particle is selected from one or more of Al, Mg, Li, Mn, Y, La, Cu, Ni, Zr, Ce, In and Ga, and the IIB-VIA semiconductor material is selected from one or more of ZnS, ZnSe and CdS, and the IIIA-VA semiconductor material is selected from one or more of InP and GaP, and the IB-IIIA-VIA family semiconductor material is selected from one or more of CuInS and CuGaS; and
$$1 \leq X \leq 10 and 1 \leq Y \leq 11 .$$

6. The composite film according to claim 3, wherein the inorganic nanoparticle is selected from the p-type semiconductor nanoparticle;
a sum of a thicknesses of the first film ranges between 10 nm-100 nm;
a thickness of the composite film ranges between 11 nm-133 nm;
the p-type semiconductor nanoparticle is selected from one or more of second doped metal oxide particle, second undoped metal oxide particle, metal sulfide, metal selenide and metal nitride, and a metal oxide in the second doped metal oxide particle and a metal oxide in the second undoped metal oxide particle is independently selected from one or more of MoO₃, WO₃, NiO, CrO₃, CuO, Cu₂O and V₂O₅, and a doping element in the second doped metal oxide particle is selected from one or more of Mo, W, Ni, Cr, Cu and V, and the metal sulfide is selected from one or more of CuS, MoS₃ and WS₃, and the metal selenide is selected from one or more of MoSe₃ and WSe₃, and the metal nitride is selected from p-type gallium nitride; and
$$1 \leq X \leq 10 and 1 \leq Y \leq 11 .$$

7. The composite film according to claim 3, wherein the first II-VI compound is selected from one or more of BaS, CaS, CdS, CdTe, Hg₁₋ₐCdₐTe, HgTe, MnTe, SrS, SrSi_{1-b}Se_{b}, ZnS, ZnSe, ZnS_{1-c}Se_{c}, Cd₁₋ₐMn_{d}Te and ZnTe, wherein 0<a<1, 0<b<1, 0<c<1 and 0<d<1;
the first III-V compound is selected from one or more of AlAs, AlₑGa₁₋ₑAs, AlP, GaAs, Ga_{f}In_{1-f}As, GagIn_{1-g}P, GaP, InAs, InP, AlN, GaN and InN, wherein 0<e<1, 0<f<1 and 0<g<1;
the first IV-IV compound includes TiC;
the he IV-V compound is selected from one or more of TiN and SiNₕ, wherein 1≤h<4;
the V-V compound includes NbN;
the VI-V compound includes MON;
the VI-VI compound is selected from one or more of WS₂ and WS₃;
the VIII-V compound is selected from one or more of CoP and Co₂P; and
the second film is prepared by atomic layer deposition.

8. A preparation method of a composite film, comprising:
providing a first film, wherein a material of the first film comprises inorganic nanoparticle:
forming a second film on the first film, wherein a material of the second film comprises inorganic metal compound; and
alternately forming X-1 layers of first film and Y-1 layers of second film on the second film in turn, wherein X≥1 and Y≥1 to obtain a composite film; or
providing a second film, wherein a material of the second film comprises inorganic metal compound:
forming a first film on the second film, wherein a material of the first film comprises inorganic nanoparticle; and
alternately forming Y-1 layers of second film and X-1 layers of first film on the first film in turn, wherein X≥1 and Y≥1 to obtain a composite film.

9. The preparation method according to claim 8, wherein X=Y+x, and x is 0 or 1, and 1≤X≤12 and 1≤Y≤13;
the inorganic nanoparticle is selected from one of quantum dot, n-type semiconductor nanoparticle and p-type semiconductor nanoparticle, and an average particle size of the inorganic nanoparticle ranges between 1 nm-20 nm.

10. The preparation method according to claim 8, wherein the first film is prepared by a solution method; and
the second film is prepared by atomic layer deposition; and the atomic layer deposition comprising introducing a cationic precursor and an anionic precursor to form the second film.

11. The preparation method according to claim 10, wherein the cationic precursor is selected from one or more of Sr precursor, Ba precursor, Y precursor, Ti precursor, Nb precursor, Ta precursor, Mo precursor, W precursor, Mn precursor, Co precursor, Ni precursor, Zn precursor, Cd precursor, Hg precursor, Al precursor, Ga precursor, In precursor, Sn precursor and Sb precursor;
the anion precursor is selected from one or more of C precursor, N precursor, P precursor, As precursor, O precursor, S precursor, Se precursor, Te precursor and F precursor.

12. The preparation method according to claim 11, wherein the Sr precursor is selected from strontium diisobutyrate; the Ba precursor is selected from barium diisobutyrate; the Y precursor is selected from yttrium triisobutyrate; the Ti precursor is selected from one or more of tetra(dimethylamino) titanium and titanium tetrachloride; the Nb precursor is selected from niobium pentachloride; the Ta precursor is selected from tantalum pentachloride; the Mo precursor is selected from molybdenum hexafluoride; the W precursor is selected from tungsten hexafluoride; the Mn precursor is selected from manganese triisobutyrate; the Co precursor is selected from one or more of cobalt triphosphate and cobaltocene; the Ni precursor is selected from nickel metallocene; the Zn precursor is selected from diethyl zinc; the Cd precursor is selected from cadmium pyruvate; the Hg precursor is selected from mercury difluoro pyruvate; the Al precursor is selected from trimethyl aluminum; the Ga precursor is selected from trimethyl gallium; the In precursor is selected from indium cyclopentadiene; the Sn precursor is selected from tetra-dimethylaminotin; and the Sb precursor is selected from antimony trichloride;
the C precursor is selected from methane; and the N precursor is selected from ammonia gas; and the P precursor is selected from one or more of phosphine and trialkylphosphine; and the As precursor is selected from hydrogen arsenide; and the O precursor is selected from ozone; and the S precursor is selected from hydrogen sulfide; and the Se precursor is selected from hydrogen selenide; and the Te precursor is selected from tellurium tetrachloride; and the F precursor is selected from nitrogen trifluoride.

13. The preparation method according to claim 10, wherein the introducing a cationic precursor and an anionic precursor is carried out in an inert atmosphere, and an inert gas in the inert atmosphere is selected from one or more of helium, neon, argon, krypton, xenon and nitrogen;
the introducing a cationic precursor and an anionic precursor is carried out in a heated atmosphere, and a temperature of the heated atmosphere ranges between 100° C.-300° C.; and
the introducing a cationic precursor and an anionic precursor is carried out in a vacuum atmosphere, and a vacuum degree of the vacuum atmosphere ranges between 0.001 Torr-0.1 Torr.

14. The preparation method according to claim 10, wherein the introducing a cationic precursor and an anionic precursor comprising: introducing the cationic precursor first and then introducing the anionic precursor, and a time for introducing the cationic precursor and the anionic precursor independently ranges between 0.01s-0.5s.

15. The preparation method according to claim 14, wherein after introducing the cationic precursor, and before introducing the anionic precursor, it further comprising introducing clean gas, and the cleaning gas is selected from one or more of helium, neon, argon, krypton, xenon and nitrogen, and a time for introducing the clean gas ranges between 5s-15s;
after introducing the cationic precursor and the anionic precursor, the cationic precursor and the anionic precursor are recycled introducing to form the second film, and a time of recycling introducing the cationic precursor and the anionic precursor ranges between 2-8 times.

16. A light-emitting device, comprising:
an anode;
a cathode; and
a functional layer, between the anode and the cathode, comprising a composite film, and the composite film comprising:
X layers of first film; and
Y layers of second film alternately stacked with X layers of the first film;
wherein X is an integer ≥1 and Y is an integer ≥1, and a material of the first film comprises inorganic nanoparticle, and a material of the second film comprises inorganic metal compound.

17. The light-emitting device according to claim 16, wherein the inorganic metal compound is selected from one or more of the first II-VI compound, the first III-V compound, the first IV-IV compound, the IV-V compound, the V-V compound, the VI-V compound, the VI-VI compound and the VIII-V compound; and
the first II-VI compound is selected from one or more of BaS, CaS, CdS, CdTe, Hg₁₋ₐCdₐTe, HgTe, MnTe, SrS, SrSi_{1-b}Se_{b}, ZnS, ZnSe, ZnS_{1-c}Se_{c}, Cd_{1-d}Mn_{d}Te and ZnTe, wherein 0<a<1, 0<b<1, 0<c<1 and 0<d<1; the first III-V compound is selected from one or more of AlAs, AlₑGa₁₋ₑAs, AlP, GaAs, Ga_{f}In_{1-f}As, GagIn1-gP, GaP, InAs, InP, AlN, GaN and InN, wherein 0<e<1, 0<f<1 and 0<g<1; the first IV-IV compound includes TiC; the he IV-V compound is selected from one or more of TiN and SiNₕ, wherein 1≤h≤4; the V-V compound includes NbN; the VI-V compound includes MON; the VI-VI compound is selected from one or more of WS₂ and WS₃; and the VIII-V compound is selected from one or more of CoP and Co₂P.

18. The light-emitting device according to claim 16, wherein the functional layer comprising:
a hole functional layer, located on the anode;
an active layer, located on the hole functional layer; and
an electronic functional layer located on the active layer;
wherein one or more of the hole functional layer, the active layer, and the electronic functional layer comprises the composite film.

19. The light-emitting device according to claim 18, wherein the active layer comprises the composite film, and the inorganic nanoparticle is selected from quantum dot; or
the hole functional layer comprises the composite film, and the inorganic nanoparticle is selected from p-type semiconductor nanoparticle; or
the electronic functional layer comprises the composite film, and the inorganic nanoparticle is selected from n-type semiconductor nanoparticle.

20. The light-emitting device according to claim 16, wherein a material of the anode and the cathode is each independently selected from one or more of metal, carbon material and metal oxide, and the metal is selected from one or more of Al, Ag, Cu, Mo, Au, Ba, Ca, Yb and Mg, and the carbon material is selected from one or more of graphite, carbon nanotubes, graphene and carbon fiber, and the metal oxide is selected from one or more of metal oxide electrode or composite electrode with metal sandwiched between doped or undoped transparent metal oxide, and a material of the metal oxide electrode is selected from one or more of ITO, FTO, ATO, AZO, GZO, IZO, MZO, MoO₃ and AMO, and the composite electrode is selected from one or more of AZO/Ag/AZO, AZO/AVAZO, ITO/Ag/ITO, ITO/AI/ITO, ZnO/Ag/ZnO, ZnO/Al/ZnO, ZnS/Ag/ZnS, ZnS/Al/ZnS, TiO₂/Ag/TiO₂ and TiO₂/Al/TiO₂.
